(19) United States
(12) Patent Application Publication
(10) Pub. No.: US 2008/0116508 A1
(43) Pub. Date: May 22, 2008

(54) Semiconductor memory device

(75) Inventors: Takahisa HAYASHI, Tokyo (JP); Shinya OZAWA, Tokyo (JP); Koji TAKAYA, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/979,413

(22) Filed: Nov. 2, 2007

(30) Foreign Application Priority Data
Nov. 17, 2006 (JP) 2006-311229

(51) Int. Cl. H01L 29/792

(52) U.S. Cl. 257/324; 257/E29.309

(57) ABSTRACT

A semiconductor memory device of the invention includes a substrate, a convex semiconductor formed convexly on the substrate, a channel region formed within the convex semiconductor, source and drain regions formed within the convex semiconductor so as to sandwich the channel region, a resistance transition region formed so as to be sandwiched at least between the channel region and the source region or between the channel region and the drain region within the convex semiconductor, a gate electrode covering at least both side-faces of a part where the channel region of the convex semiconductor is formed and charge trapping layers covering at least both side-faces of a part of the convex semiconductor where the resistance transition regions are formed. Due to this configuration, there is provided the semiconductor memory device that can prevent its erroneous operation.

### CROSS-REFERENCE TO RELATED APPLICATION

This application claims priority under 35 USC 119 from Japanese Patent Application No. 2006-311229, the disclosure of which is incorporated by reference herein.

### BACKGROUND OF THE INVENTION

1. Field of the Invention

The present invention relates to a semiconductor memory device and more specifically to a semiconductor memory device that can be utilized for a semiconductor non-volatile memory for example.

2. Description of Related Art

Presently, a semiconductor non-volatile memory is utilized as a memory in low-power equipments such as a cellular phone because it requires no electric power to retain stored information.

As one of them, there has been proposed a semiconductor non-volatile memory having charge trapping layers provided so as to sandwich a gate electrode (see Japanese Patent Application Laid-open (JP-A) No. 2006-24680). Such semiconductor non-volatile memory functions as a memory by trapping electrons in the charge trapping layer. That is, the non-volatile memory functions as the memory by changing an amount of electric current in the memory (transistor) from the electron whether or not it exists in the charge trapping layer and by reading the change as data of “0” and “1”.

Meanwhile, elements used in semiconductor memory devices including the semiconductor non-volatile memory are being remarkably miniturized and even a fin-type field effect transistor that is one type of three-dimensional MIS-type semiconductor memory devices has come to be proposed as disclosed in JP-A Nos. 2003-163356, 2004-214413 and 2004-172559 and U.S. Pat. No. 6,413,802 for example.

However, if the miniturization of the semiconductor non-volatile memory having the charge trapping layer advances, dimensions of a gate is reduced and a width of a gate electrode is also reduced. Then, because a channel width is reduced, a value of electric current flowing through the memory (transistor) is also reduced. That makes it difficult to read data and becomes a cause of erroneous operation.

### SUMMARY OF THE INVENTION

Accordingly, it is an object of the invention to provide a semiconductor memory device that prevents its erroneous operation.

The aforementioned problems may be solved by the following means. That is, according to an aspect of the present invention, there is provided a semiconductor memory device, including: a substrate; a convex semiconductor formed convexly on the substrate; a channel region formed within the convex semiconductor; a source region and a drain region formed within the convex semiconductor so as to sandwich the channel region therebetween; a resistance transition region formed at least between the channel region and the source region, or between the channel region and the drain region, within the convex semiconductor; a gate electrode covering at least both side-faces of a part where the channel region of the convex semiconductor is formed; and a charge trapping layer covering at least both side-faces of a part where the resistance transition region of the convex semiconductor is formed.

Preferably, in the semiconductor memory device of the invention, the charge trapping layer has a laminated layer including a first silicon oxide layer, a silicon nitride layer formed on the first silicon oxide layer and a second silicon oxide layer formed on the silicon nitride layer.

The invention can provide the semiconductor memory device that prevents its erroneous operation.

### BRIEF DESCRIPTION OF THE DRAWINGS

Preferred exemplary embodiments of the present invention will be described in detail based on the following figures, wherein:

FIG. 1 is a schematic perspective view showing a semiconductor memory device of an embodiment;

FIG. 2 is a schematic plan view showing the semiconductor memory device of the embodiment;

FIG. 3 is a section view taken along a line A-A in FIGS. 1 and 2; and

FIG. 4 is a section view taken along a line B-B in FIGS. 1 and 2.

### DETAILED DESCRIPTION OF THE INVENTION

An embodiment of the invention will be explained with reference to the drawings. It is noted that components having the same or corresponding functions and operations will be denoted by the same reference numerals and overlapped explanation thereof will be omitted.

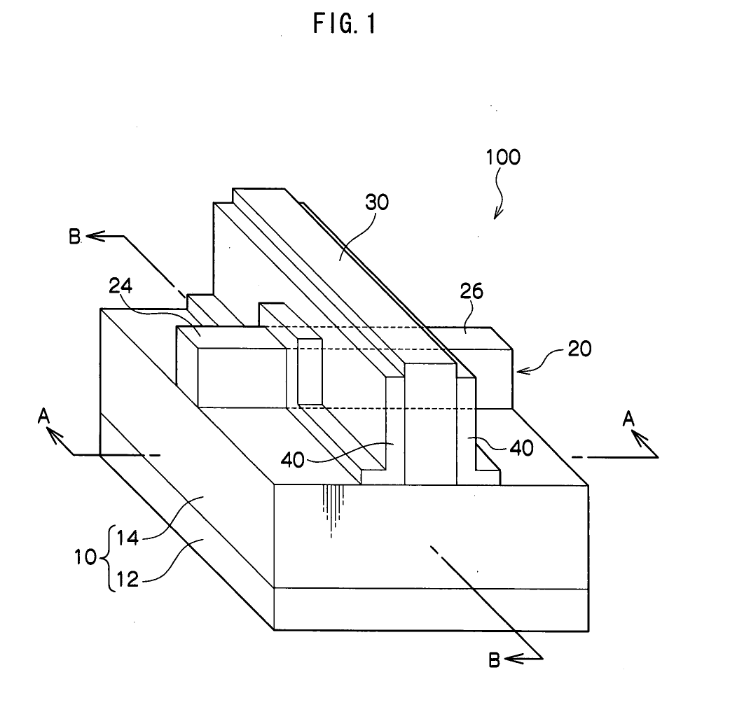

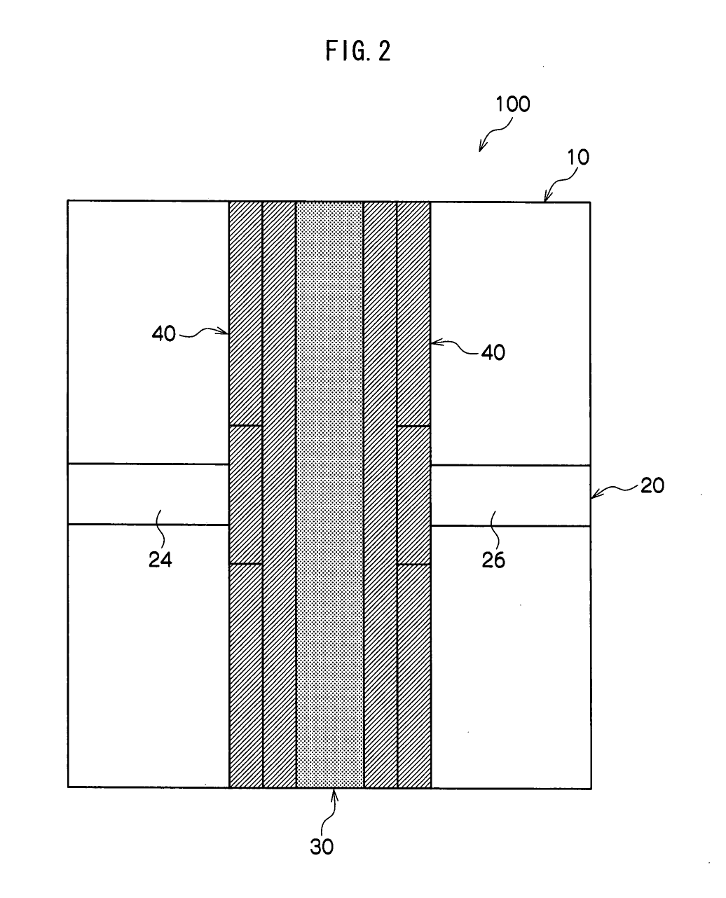

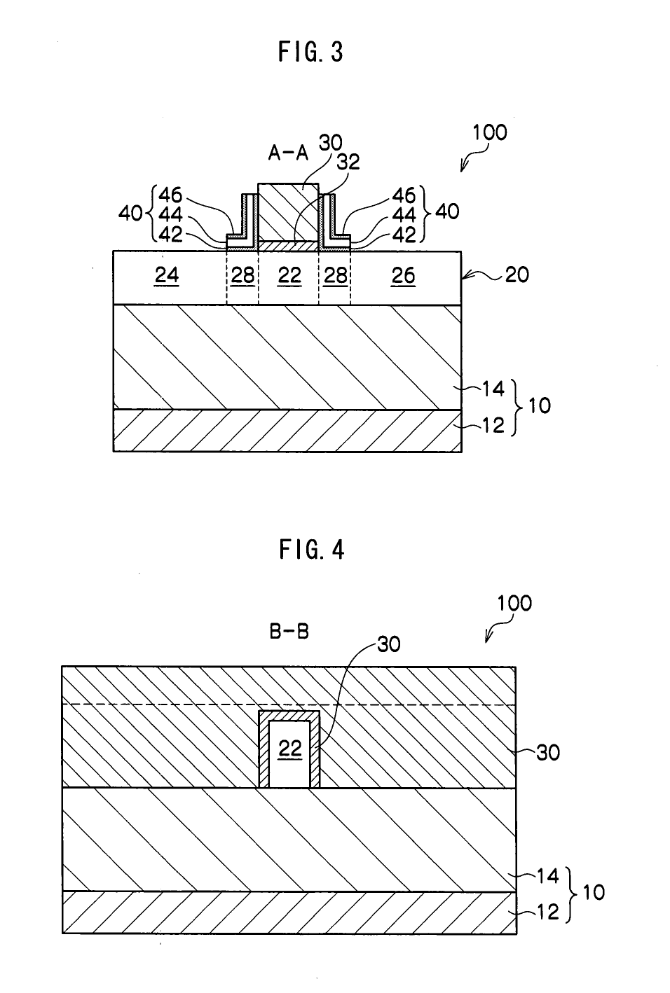

FIG. 1 is a schematic perspective view showing a semiconductor memory device of an embodiment, FIG. 2 is a schematic plan view showing the semiconductor memory device of the embodiment, FIG. 3 is a section view taken along a line A-A in FIGS. 1 and 2, and FIG. 4 is a section view taken along a line B-B in FIGS. 1 and 2.

The semiconductor memory device 100 of the present embodiment is used as a semiconductor non-volatile memory for example and has a convex semiconductor 20, a gate electrode 30 and a charge trapping layer 40 formed on a substrate 10 having an element-isolation insulating layer 14 on a silicon substrate 12 as shown in FIGS. 1 through 4.

The convex semiconductor 20 is formed, for example, into a shape of a rectangular parallelepiped so as to protrude from the surface of the substrate 10.

The convex semiconductor 20 is semiconductor that becomes an active region and is composed of p-type silicon for example. Then, in the convex semiconductor 20, a source region 24 and a drain region 26 are formed as n⁺-type impurity diffusion regions at the both ends of the convex semiconductor 20 and a channel region 22 is formed between the source region 24 and the drain region 26. Then, resistance transition regions 28 that are formed respectively as n⁺-type impurity diffusion regions having lower impurity concentration than those of the source and drain regions 24 and 26 are formed between the source region 24 and the channel region 22 and between the drain region 26 and the channel region 22.

That is, the convex semiconductor 20 has the first conductive (p-type) channel region 22 formed at a center part thereof, the resistance transition regions 28 formed so as to sandwich the channel region 22 and the source and drain regions 24 and 26 formed so as to sandwich the channel region 22 and the resistance transition regions 28.

The gate electrode 30 is formed so as to three-dimensionally intersect with the convex semiconductor 20 while covering the both opposing side-faces and an upper face of the part of the convex semiconductor 20 where the channel region 22 is formed and while intersecting with a longitudinal direction of the convex semiconductor 20 at right angles. The gate electrode 30 is made of poly-silicon (polycrystalline silicon) for example and is formed so as to cover the convex semiconductor 20 through an intermediary of a gate oxide layer 32 made of a silicon oxide layer for example.

Charge trapping layers 40 are formed so as to three-dimensionally intersect with the convex semiconductor 20 while covering both opposing side-faces and an upper face of parts of the convex semiconductor 20 where the resistance transition regions 28 are formed and while intersecting at right angles with the longitudinal direction of the convex semiconductor 20. The charge trapping layers 40 are formed so as to sandwich the gate electrode 30 from the both side-faces thereof.

The charge trapping layer 40 has a laminated structure (ONO: Oxide, Nitride and Oxide) including, in order from the side of the gate electrode 30 and the resistance transition region 28, a bottom oxide layer 42 made of a silicon oxide (SiO) layer, a nitride silicon (SiN) layer 44 formed on the bottom oxide layer 42 and a top oxide layer 46 made of silicon oxide (SiO) layer formed on the silicon nitride layer 44 for example.

The semiconductor memory device 100 of the embodiment constructed as described above causes changes of electric currents flowing through between the source and drain regions 24 and 26 because the resistance transition regions 28 are modulated by an electric charge whether or not it exists in the charge trapping layer 40, a quantity of electric charges and polarities (plus and minus) thereof by trapping the electric charges in the silicon nitride layer 44 of the charge trapping layer 40 and by drawing the trapped charges out of the silicon nitride layer 44 of the charge trapping layer 40 (or by injecting an electric charge having a polarity opposite from that of the trapped charge).

Specifically, when an electric charge is injected to the charge trapping layer 40 so that it traps the charge for example, an electric current decreases because resistance of the resistance transition region 28 increases. When no charge is trapped in the charge trapping layer 40 in contrary, an electric current flows fully because a value of resistance of the resistance transition region 28 is low. Then, it becomes possible to record or read information of one bit by reading states in which the current is decreased and in which the current flows and by correlating them with logical values “0” or “1”. Because there are two charge trapping layers 40, it is possible to record or read information of two bits.

It is noted that trapping of the charge to the charge trapping layer 40 on the side of the source region 24 is carried out by applying positive voltage to the source region 24 and the gate electrode 30 and by setting the drain region 26 at earth voltage. Meanwhile, trapping of the charge to the charge trapping layer 40 on the side of the drain region 26 is carried out by applying positive voltage to the drain region 26 and the gate electrode 30 and by setting the source region 24 at the earth voltage.

Recording and reading are thus carried out by reading the value of current flowing through between the source and drain regions 24 and 26. However, the convex semiconductor (i.e., the active region) in which the channel region 22, the source region 24 and the drain region 26 are formed is formed so as to protrude on the substrate 10 in the present embodiment, so that an electric current flows widely in a height direction (length along a direction intersecting at right angles with the face of the substrate) even if a width along the direction of the face of the substrate is reduced due to the miniturization. That is, a channel width necessary for reading is assured (largely) in the height direction.

Therefore, the value of current flowing through between the source and drain regions 24 and 26 is fully assured. That is, a difference between values of currents in the states when the current is decreased and when the current flows is fully assured, facilitating reading and preventing erroneous operation even if the device is miniturized.

In addition to that, it is possible to control the value of current flowing through between the source and drain regions 24 and 26 by controlling the height of the convex semiconductor 20 in which the channel region 22, the source region 24 and the drain region 26 are formed. That is, it is possible to fully assure the difference of values of currents, to readily realize the reading and discrimination and to record or read information of multi-bits by correlating the differences to three or more logical values (e.g., “0”, “1” or “2”) even if the value of current flowing through between the source and drain regions 24 and 26 is controlled stepwise by controlling the quantity of charges trapped by the charge trapping layer 40 by designing the height of the convex semiconductor 20 high to fully assure a maximum value of the value of current flowing through between the source and drain regions 24 and 26.

Specifically, it is possible to control the quantity of charges in the charge trapping layer 40 into states in which the electric charges are trapped by a first quantity of charges, in which electric charges are trapped by a second quantity of charges that is lower than the first quantity of charges and in which no electric charge is trapped and to read the value of current flowing through between the source and drain regions 24 and 26 as a first state in which the current is reduced, a second state in which current flows more than the first state and as a state in which current flows more than the first and second states.

It is noted that although the mode of the single device (semiconductor non-volatile memory cell) has been explained in the present embodiment, the invention is not limited only to that and is normally adapted so as to array the devices. Because it becomes possible to record and read the information of multi-bits by one charge trapping layer 40 and to record/read multi-bit information to/from one device (semiconductor non-volatile memory cell) according to the present embodiment, it becomes also possible to enhance information recording density per unit area by arraying the single device used as the non-volatile memory.

Furthermore, although the mode having the two charge trapping layers has been explained in the present embodiment, the mode may be one having just one charge trapping layer.

It is needless to say that the present embodiment should be construed to be not definitive but rather to be realizable within a scope meeting the requirements of the invention.

What is claimed is:

1. A semiconductor memory device, comprising:
a substrate;
a convex semiconductor formed convexly on the substrate;
a channel region formed within the convex semiconductor;
a source region and a drain region formed within the convex semiconductor so as to sandwich the channel region therebetween;
a resistance transition region formed at least between the channel region and the source region, or between the channel region and the drain region, within the convex semiconductor;
a gate electrode covering at least both side-faces of a part where the channel region of the convex semiconductor is formed; and
a charge trapping layer covering at least both side-faces of a part where the resistance transition region of the convex semiconductor is formed.

2. The semiconductor memory device according to claim 1, wherein the charge trapping layer includes a laminated layer including a first silicon oxide layer, a silicon nitride layer formed on the first silicon oxide layer and a second silicon oxide layer formed on the silicon nitride layer.

3. The semiconductor memory device according to claim 1, wherein the convex semiconductor is formed into a shape of a rectangular parallelepiped so as to protrude from the surface of the substrate.

4. The semiconductor memory device according to claim 1, wherein the gate electrode is formed so as to three-dimensionally intersect with the convex semiconductor while covering opposing both side-faces and an upper face of a part of the convex semiconductor where the channel region is formed and while intersecting at right angles with a longitudinal direction of the convex semiconductor.

5. The semiconductor memory device according to claim 1, wherein the charge trapping layer is formed so as to three-dimensionally intersect with the convex semiconductor while covering opposing both side-faces and an upper face of a part of the convex semiconductor where the resistance transition region is formed and while intersecting at right angles with a longitudinal direction of the convex semiconductor.

6. The semiconductor memory device according to claim 4, wherein the charge trapping layer is formed so as to three-dimensionally intersect with the convex semiconductor while covering the opposing both side-faces and the upper face of the part of the convex semiconductor where the resistance transition region is formed and while intersecting at right angles with the longitudinal direction of the convex semiconductor.

7. The semiconductor memory device according to claim 6, wherein the charge trapping layers are formed so as to sandwich the gate electrode from the both side-faces thereof.
